(19) United States
(12) Patent Application Publication
(10) Pub. No.: US 2026/0334111 A1
(43) Pub. Date: Oct. 22, 2026

(54) HORIZONTALLY DOPED ALD ULTRATHIN FILMS AND MANUFACTURING METHOD THEREOF

(71) Applicant: AJOU UNIVERSITY INDUSTRY-ACADEMIC COOPERATION FOUNDATION, Gyeonggi-do (KR)

(72) Inventors: Il Kwon OH, Gyeonggi-do (KR); BYUNG-HA KWAK, Seoul (KR)

(21) Appl. No.: 19/466,687

(22) Filed: Feb. 2, 2026

(30) Foreign Application Priority Data
Feb. 10, 2025 (KR) 10-2025-0016878

(51) Int. Cl. H10P 14/692; C23C 16/40; C23C 16/455; C23C 16/56; H10P 14/60

(52) U.S. Cl. CPC H10P 14/69392; C23C 16/405; C23C 16/45542; C23C 16/56; H10P 14/6336; H10P 14/6339; H10P 14/6544

(57) ABSTRACT

The present disclosure relates to an ultrathin dysprosium (Dy)-doped hafnium oxide (HfOx) film fabricated by a horizontally doped atomic layer deposition (ALD) method rather than a conventional vertically doped ALD method. By forming the Dy-doped HfOx ultrathin film using the horizontally doped ALD method, the present disclosure addresses difficulties in forming extremely thin ALD films and reduces high leakage current issues associated with conventional ALD ultrathin films.

### CROSS-REFERENCE TO RELATED APPLICATION

The present application claims priority under 35 U.S.C. § 119 (a) to Korean patent application number 10⁻²⁰²⁵-0016878 filed on Feb. 10, 2025, in the Korean Intellectual Property Office, the entire disclosure of which is incorporated by reference herein.

### BACKGROUND

### 1. Technical Field

The present disclosure relates to a dysprosium (Dy)-doped hafnium oxide (HfOx) ultrathin film fabricated by a horizontally doped atomic layer deposition (ALD) method rather than a conventional vertically doped ALD method, and to a method for manufacturing the same.

### 2. Related Art

Current semiconductor manufacturing processes inherently require nanoscale technologies. In particular, oxide materials, which are among essential materials used in semiconductors, are required to satisfy a trade-off characteristic in which a dielectric constant is increased while a leakage current is suppressed even at a reduced thickness. In particular, it is extremely challenging to achieve a required dielectric constant while satisfying perfect insulating characteristics at an ultrathin thickness of 5 nm or less. Among various approaches for improving electrical properties, there is an approach that employs doping to enhance electrical properties. Among such doping technologies, techniques for improving electrical properties by doping a transition metal oxide (TMO) with a rare earth oxide (ReO) to form a rare-earth-doped transition metal oxide (ReTMO) have attracted considerable attention.

Processes for forming such thin films include various techniques; however, atomic layer deposition (ALD), which enables precise control of a film thickness at an atomic level, has attracted significant attention. In the ALD process, a precursor and a reactant are sequentially exposed to a surface, thereby allowing a thin film to be deposited consistently even on structures having uniform and high aspect ratios (HARs). Accordingly, the ALD process has become an indispensable technique in the modern semiconductor industry, in which nanoscale thin-film design is of critical importance.

When forming ReTMO thin film using such an ALD process, a vertically doped scheme is typically employed, in which process cycles of a first precursor are performed for a desired number of times, followed by process cycles of a second precursor. Although such a vertically doped approach has an advantage in that doping concentration can be adjusted by controlling a cycle ratio, it is limited in adjusting a desired doping concentration by cycle control in an ultrathin film region having a thickness of 5 nm or less.

### PRIOR ART DOCUMENTS

### Patent Documents

(Patent Document 1) U.S. Patent Application Publication No. US 2008-0315292, published on Dec. 25, 2008.
(Patent Document 2) Korean Registered Patent No. KR 10⁻⁰⁴⁸⁶⁶³⁷, issued on May 3, 2005.

### SUMMARY

The present disclosure is directed to providing an ultrathin film and a method for manufacturing the same, in which, in forming an ultrathin film using atomic layer deposition (ALD), a horizontally doped ALD method is employed instead of a conventional vertically doped ALD method, thereby overcoming material property limitations of ultrathin films manufactured by conventional vertically doped ALD methods.

In order to solve the above problems, the present disclosure performs a method for manufacturing a dysprosium (Dy)-doped hafnium oxide ultrathin film by an atomic layer deposition (ALD) process, the method including performing the ALD process using one super cycle including a first step to a sixth step, the one super cycle including a first step of supplying a vaporized first precursor into a reaction chamber through a carrier gas to form a first deposition layer on a target substrate; a second step of purging an interior of the reaction chamber with a purge gas; a third step of supplying a vaporized second precursor into the reaction chamber to form a second deposition layer on the first deposition layer; a fourth step of purging the interior of the reaction chamber after performing the third step with the purge gas; a fifth step of introducing and reacting an O₂-containing gas into the reaction chamber after performing the fourth step; and a sixth step of purging the interior of the reaction chamber after performing the fifth step with the purge gas.

In a preferred embodiment of the present disclosure, the first precursor and the second precursor each include a hafnium (Hf) precursor or a dysprosium (Dy) precursor, and the first precursor and the second precursor are different from each other.

In a preferred embodiment of the present disclosure, the ultrathin film may be formed as a single-layer structure by performing the one super cycle once, or may be formed as a multilayer structure by repeatedly performing the one super cycle.

In a preferred embodiment of the present disclosure, the ALD process may be performed by a plasma-enhanced atomic layer deposition (PE-ALD) process.

In a preferred embodiment of the present disclosure, a temperature of the target substrate in the first step may be 200 °C to 275 °C.

In a preferred embodiment of the present disclosure, each of the first step, the third step, and the fifth step may be performed at a process temperature of 200 °C to 275 °C.

In a preferred embodiment of the present disclosure, the method may further include performing an annealing process after completion of the ALD process.

In a preferred embodiment of the present disclosure, the annealing process may be performed by annealing the ultrathin film represented by Chemical Formula 1, which is formed by performing step 6, at a temperature of 500 to 900 °C under a vacuum atmosphere or an inert gas atmosphere.

(Dy)ₐHf_{b}O_{c} [Chemical Formula 1]

In Chemical Formula 1, a, b, and c represent molar ratios, and when a +b+c=1, a satisfies 0.001≤a≤0.010 and b satisfies 0.250≤b≤0.350.

In a preferred embodiment of the present disclosure, when the annealing temperature is lower than 700 °C, the annealed ultrathin film may have an amorphous structure.

In a preferred embodiment of the present disclosure, when the annealing temperature exceeds 700 °C, the annealed ultrathin film may have a tetragonal crystal structure.

In a preferred embodiment of the present disclosure, the hafnium (Hf) precursor may include at least one selected from the group consisting of HfCl₁₄, tetrakis(ethylmethylamido) hafnium (IV), tetrakis(dimethylamido) hafnium (IV), and Cp-Hf.

In a preferred embodiment of the present disclosure, the dysprosium (Dy) precursor may include at least one selected from the group consisting of Dy(iPrCp)₂(iPr-N-amd), DyCl₃, and tris(2,2,6,6-tetramethyl-3,5-heptanedionato) dysprosium (III).

In a preferred embodiment of the present disclosure, after completion of the ALD process comprising steps 1 to 6, an oxidation barrier film may be further formed on an outwardly exposed surface of the ALD deposition layer, followed by performing an annealing process.

In a preferred embodiment of the present disclosure, the oxidation barrier film may be a silicon nitride (SiNₓ) ALD deposition layer with a thickness of 1 to 10 nm.

In addition, the present disclosure relates to a horizontally doped atomic layer deposition (ALD) ultrathin film manufactured by the method described above, the ultrathin film comprising a compound represented by Chemical Formula 1 and having a thickness of 10 nm or less.

(Dy)ₐHf_{b}O_{c} [Chemical Formula 1]

In Chemical Formula 1, a, b, and c represent molar ratios, and when a +b+c=1, a satisfies 0.001≤a≤0.010 and b satisfies 0.250≤b≤0.350.

In a preferred embodiment of the present disclosure, when the ultrathin film of the present disclosure is a single thin film having a thickness of 4.5 nm to 5.5 nm, the ultrathin film has a current density of 1.0×10⁻⁷ A/cm² to 9.0×10⁻⁵ A/cm² at an electric field of −1 MV/cm, as measured by a manual probe contact-type current-voltage measurement method.

In addition, the present disclosure is applicable to using the ultrathin film described above as a semiconductor material.

This disclosure was supported by a national research and development program of the Republic of Korea.
[Assignment Unique Number] Not assigned
[Assignment Number] S-2022-G0001-00440
[Name of the Ministry] Korea Ministry of Science and ICT
[Name of the Assignment Managing (Professional) Organization] National Research Foundation of Korea
[Research Project Title] University Academic Promotion Research Fund (Autonomous Type)
[Assignment Title] Research on High-Quality Rare-Earth-Metal-Doped Transition Metal Oxides Based on Fine Control of Elemental Distribution
[Name of the Organization Performing the Assignment] Ajou University
[Research Period] Oct. 1, 2022 to Sep. 30, 2023

The ultrathin film manufacturing method according to the present disclosure enables the manufacture of an ultrathin film having a thickness of 10 nm or less, preferably 5 nm or less, with a high fabrication yield, and the ultrathin film thus manufactured exhibits relatively lower leakage current as compared with ultrathin films manufactured by conventional vertically doped ALD deposition processes.

### BRIEF DESCRIPTION OF THE DRAWINGS

FIG. 1 is a schematic process diagram of a conventional vertically doped atomic layer deposition (ALD) process.

FIGS. 2A and 2B are schematic process diagrams of a horizontally doped ALD process according to the present disclosure.

FIG. 3 is a graph illustrating dysprosium (Dy) concentration measurement data according to a first precursor sequence and exposure time in Examples 1 and 2 performed in Experimental Example 1.

FIG. 4 is a graph illustrating atomic layer deposition (ALD) growth curves, expressed as growth per cycle (GPC), for respective ultrathin films of Example 1, Example 2, and Comparative Examples 1 and 2 performed in Experimental Example 2.

FIG. 5 is a graph illustrating X-ray diffraction (XRD) measurement results for respective ultrathin films of Examples 1 and 2 performed in Experimental Example 3.

FIG. 6 is a graph illustrating leakage current characteristic evaluation results for respective ultrathin films of Examples 1 and 2 and Comparative Examples 1 and 2 performed in Experimental Example 3.

### DETAILED DESCRIPTION OF THE EMBODIMENTS

In the present disclosure, the terms “thin film” or “ultrathin film” refer to a deposition layer and/or a film formed through atomic layer deposition (ALD).

The terminology used herein is for the purpose of describing particular embodiments only and is not intended to be limiting of the present disclosure. Expressions in the singular include plural expressions unless the context clearly indicates otherwise. In the present application, the terms “comprise or include” or “have” and the like are intended to specify the presence of stated features, numerals, steps, operations, components, or combinations thereof, but should be understood as not precluding the possibility of the presence or addition of one or more other features, numerals, steps, operations, components, or combinations thereof.

Unless otherwise defined, all terms used herein, including technical and scientific terms, have the same meanings as those commonly understood by a person having ordinary skill in the art to which the present disclosure belongs. Terms defined in generally used dictionaries are to be interpreted as having meanings consistent with their meanings in the context of the related art, and are not to be interpreted in an idealized or overly formal sense unless expressly so defined herein.

The horizontally doped ALD ultrathin film of the present disclosure may be manufactured through an atomic layer deposition (ALD) process, preferably by performing a plasma-enhanced atomic layer deposition (PE-ALD) process. The horizontally doped ALD ultrathin film is a single-layer thin film or a multilayer thin film comprising a compound represented by Chemical Formula 1 below.

(Dy)ₐHf_{b}O_{c} [Chemical Formula 1]

In Chemical Formula 1, a, b, and c represent molar ratios, and when a +b+c=1, a satisfies 0.001≤a≤0.010 and b satisfies 0.250≤b≤0.350.

In addition, the ALD ultrathin film may have a thickness of 10 nm or less, preferably 6 nm or less, and more preferably from 1.0 nm to 5.5 nm.

A method for manufacturing the horizontally doped ALD ultrathin film of the present disclosure will now be described in greater detail.

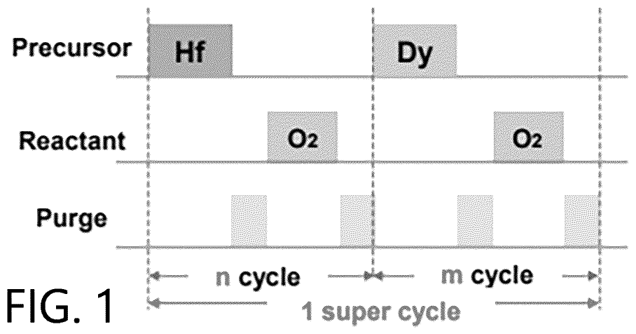

As schematically illustrated in FIG. 1, a conventional vertically doped ALD process is a deposition method in which a first precursor is reacted with a reactant, followed by introduction of a second precursor and subsequent reaction with the reactant, thereby doping an organic material or an inorganic material into a specific metal oxide. In contrast, the horizontally doped ALD process of the present disclosure is performed by sequentially exposing a first precursor and a second precursor to a surface on which a reaction is to occur, and then forming a thin film through a single reactant that reacts with both precursors. In such a horizontally doped scheme, a dopant concentration may be controlled according to an exposure order and an exposure time of the precursors based on a degree of chemical reaction and a steric hindrance effect. Among factors to be considered in the horizontally doped scheme, the steric hindrance effect may be determined by ligands of the precursors. That is, depending on the size of the ligands of the precursors, phenomena may occur in which the precursors repel each other or reaction sites on the surface are blocked by the ligands. Accordingly, precise control of doping concentrations of the first and second precursors in consideration of ligand sizes is required.

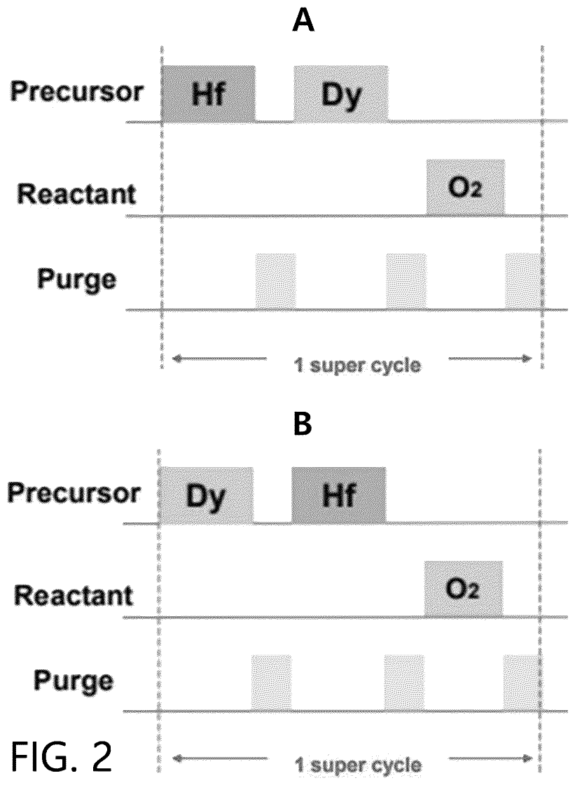

As a preferred embodiment for manufacturing the ultrathin film, the ultrathin film may be manufactured by performing an ALD deposition process in which the following process constitutes one super cycle: a first step of supplying a vaporized first precursor into a reaction chamber through a carrier gas to form a first deposition layer on a target substrate; a second step of purging the reaction chamber with a purge gas; a third step of supplying a vaporized second precursor into the reaction chamber to form a second deposition layer on the first deposition layer; a fourth step of purging the reaction chamber, in which the third step has been performed, with a purge gas; a fifth step of introducing and reacting an O₂-containing gas in the reaction chamber in which the fourth step has been performed; and a sixth step of purging the reaction chamber, in which the fifth step has been performed, with a purge gas. By repeating the super cycle, the ALD deposition process is performed to manufacture the ultrathin film. For ease of understanding, schematic diagrams of the horizontally doped ALD process of the present disclosure are illustrated in FIGS. 2A and 2B.

In the first step, the temperature of the target substrate may be from 200 °C to 275 °C, preferably from 230 °C to 275 °C, and more preferably from 250 °C to 275 °C. At this time, when the temperature of the target substrate is lower than 200 °C, a problem may occur in that reactivity of the precursor is reduced, and when the temperature of the target substrate exceeds 275 °C, a problem may occur in that the precursor is decomposed and reacts in a manner similar to chemical vapor deposition (CVD).

In addition, the process temperature of the first step may be set to from 200 °C to 275 °C, preferably from 230 °C to 275 °C, and more preferably from 250 °C to 275 °C. At this time, when the process temperature is lower than 200 °C, a problem may occur in that reactivity of the precursor is reduced, and when the process temperature exceeds 275 °C, a problem may occur in that the precursor is decomposed and reacts in a manner similar to chemical vapor deposition (CVD).

In the first step, the first precursor and the second precursor include a hafnium (Hf) precursor or a dysprosium (Dy) precursor, and the first precursor and the second precursor are different precursors from each other.

The hafnium (Hf) precursor may include at least one selected from the group consisting of HfCl₄, tetrakis(ethylmethylamido) hafnium (IV), tetrakis(dimethylamido) hafnium (IV), and Cp-Hf; preferably, the hafnium precursor may include at least one selected from the group consisting of tetrakis(ethylmethylamido) hafnium (IV), tetrakis(dimethylamido) hafnium (IV), and Cp-Hf; and more preferably, the hafnium precursor may include at least one selected from tetrakis(ethylmethylamido) hafnium (IV) and tetrakis(dimethylamido) hafnium (IV).

In addition, the dysprosium (Dy) precursor may include at least one selected from the group consisting of Dy(iPrCp)₂(iPr-N-amd), DyCl₃, and tris(2,2,6,6-tetramethyl-3,5-heptanedionato) dysprosium (III), and preferably, the dysprosium precursor may include at least one selected from Dy(iPrCp)₂(iPr-N-amd) and tris(2,2,6,6-tetramethyl-3,5-heptanedionato) dysprosium (III).

In the first step, the target substrate may be a silicon (Si) substrate, a silica (SiO₂) substrate, a platinum (Pt) substrate, a germanium (Ge) substrate, or a gallium nitride (GaN) substrate, and preferably, the target substrate may be a silicon substrate, but the present disclosure is not limited thereto.

In addition, the carrier gas in the first step may include at least one selected from argon (Ar), nitrogen (N₂), helium (He), and hydrogen (H₂), and preferably, argon may be used as the carrier gas.

The chamber in which the first to sixth steps are performed may be an ALD apparatus equipped with a showerhead-type 6-inch chamber. This is merely an example, and the present disclosure is not limited thereto.

Next, the purging of the second step is a process for removing an unreacted first precursor remaining in the chamber, and the purge gas may include nitrogen (N₂), argon (Ar), or neon (Ne), and preferably argon may be used. As a preferred example, purging may be performed by introducing and exhausting argon at a flow rate of 400 to 600 sccm for 40 to 80 seconds.

Next, the third step is a process in which the second precursor is vaporized and supplied into the chamber through a carrier gas to form a second deposition layer. In this step, the carrier gas may include at least one selected from argon (Ar), nitrogen (₂), helium (He), and hydrogen (H₂), and preferably helium may be used. In addition, the third step may be performed under the same plasma-enhanced atomic layer deposition (PE-ALD) conditions (frequency, power, and time) as those of the first step described above. An amount of the reactant to be introduced is adjusted according to an amount of the first precursor introduced in the first step, and specifically, the reactant may be introduced in an amount adjusted to satisfy molar ratios a and b of Chemical Formula 1.

Next, the purging of the fourth step is a process for removing an unreacted second precursor remaining in the chamber, and the purge gas may include nitrogen (N₄), argon (Ar), or neon (Ne), and preferably argon may be used. As a preferred example, purging may be performed by introducing and exhausting argon at a flow rate of 400 to 600 sccm for 40 to 80 seconds.

Next, the fifth step is a process in which O₂ as a reactant is supplied into the chamber through a carrier gas. In this step, the carrier gas may include at least one selected from argon (Ar), nitrogen (N₂), helium (He), and hydrogen (H₂), and preferably helium may be used. In addition, the fifth step may be performed under the same plasma-enhanced atomic layer deposition (PE-ALD) conditions (frequency, power, and time) as those of the first step described above. An amount of O₂ to be introduced is adjusted according to an amount of the first precursor and/or the second precursor introduced in the first step, and specifically, the O₂ may be introduced in an amount adjusted to satisfy molar ratios a, b, and c of Chemical Formula 1.

Next, the purging of the sixth step is a process for removing residual foreign substances, such as over-deposited reactant components, remaining in the chamber. The purging of the sixth step may be performed in the same manner and under the same conditions as those of the second step and/or the fourth step.

The first to sixth steps described above may constitute one super cycle. By performing the super cycle once, a single-layer horizontally doped ALD ultrathin film may be formed, and by performing the super cycle two or more times, a multilayer horizontally doped ALD ultrathin film may be formed.

For forming the first deposition layer in one super cycle, plasma-enhanced atomic layer deposition (PE-ALD) conditions may be appropriately set such that a distance between the substrate and the showerhead is from 5 mm to 30 mm, preferably from 10 mm to 30 mm. The plasma may be set to have a frequency of 10 to 60 MHz and a power of 50 to 400 W, preferably a frequency of 13 to 30 MHz and a power of 100 to 400 W, and more preferably a frequency of 13 to 20 MHz and a power of 200 to 320 W. Under these conditions, performing the PE-ALD for about 1 to 5 seconds is advantageous in terms of minimizing plasma-induced damage to the thin film.

After the ultrathin film is formed by performing the first to sixth steps described above, an annealing process may be further performed after completion of the ALD deposition process.

In addition, the annealing process is performed to allow the ultrathin film to obtain a lower resistivity, and may be carried out at a temperature of 500 °C to 900 °C under a vacuum atmosphere or an inert gas atmosphere including helium (He), nitrogen (N₂), or argon (Ar).

Depending on annealing temperature conditions, crystallinity of the ultrathin film may vary. When an annealing temperature is lower than 700 °C, preferably lower than 650 °C, an annealed ultrathin film comprising the compound represented by Chemical Formula 1 may exhibit an amorphous characteristic.

In addition, when the annealing temperature is higher than 700 °C, preferably higher than 750 °C, the annealed ultrathin film comprising the compound represented by Chemical Formula 1 may have a tetragonal crystal structure.

Further, if necessary, after the ALD ultrathin film is manufactured by performing the first to sixth steps, an oxidation barrier layer may be further formed on an externally exposed surface, and then an annealing process may be performed.

As a preferred embodiment of the oxidation barrier layer, the oxidation barrier layer may be a silicon nitride (SiNₓ) ALD deposition layer having a thickness of 1 nm to 10 nm, preferably 1 nm to 5 nm, and more preferably 1 nm to 3 nm.

The horizontally doped ALD ultrathin film of the present disclosure manufactured by the method described above exhibits electrical characteristics having low leakage current.

Specifically, when the ultrathin film is a single thin film having a thickness of 4.5 nm to 5.5 nm, a current density measured at an electric field of −1 MV/cm using a contact-type current-voltage measurement method with manual probes may satisfy a range of 1.0×10⁻⁷ A/cm² to 9.0×10⁻⁵ A/cm². In addition, in a process of manufacturing the ultrathin film through the horizontally doped ALD process, the current density may vary depending on the type of the first precursor.

As a specific example, in the ultrathin film manufacturing process of the present disclosure described above, when the first precursor in the first step is an Hf precursor and the second precursor is a Dy precursor, the manufactured ultrathin film, when formed as a single thin film having a thickness of 4.5 nm to 5.5 nm, may have a current density of 1.0×10⁻⁵ A/cm² to 9.0×10⁻⁵ A/cm² at an electric field of −1 MV/cm, preferably 5.0×10⁻⁵ A/cm² to 8.5×10⁻⁵ A/cm².

In addition, when, in the first step, the first precursor is a Dy precursor and the second precursor is an Hf precursor, the manufactured ultrathin film, when formed as a single thin film having a thickness of 4.5 nm to 5.5 nm, may have a current density of 1.0×10⁻⁷ A/cm² to 9.0×10⁻⁷ A/cm² at an electric field of −1 MV/cm, preferably 5.0×10⁻⁷ A/cm² to 9.0×10⁻⁷ A/cm².

The horizontally doped ALD ultrathin film of the present disclosure manufactured by the method described above is advantageous for forming an ultrathin film, and has low leakage current, and thus is advantageous for application as a semiconductor material.

Hereinafter, the present disclosure will be described in more detail with reference to Examples. However, the following Examples are not intended to limit the scope of the present disclosure, and should be construed as being provided only for facilitating understanding of the present disclosure.

### EXAMPLES

### Example 1: Preparation of Ultrathin Film by Horizontally Doped ALD (First Precursor=Dy Precursor)

An ultrathin film was prepared by plasma-enhanced atomic layer deposition (PE-ALD) using an ALD apparatus equipped with a showerhead-type 6-inch chamber, as described below.

In this case, a distance between a target substrate (Si substrate) and the showerhead in the chamber was fixed at 15 mm. In addition, a temperature of the target substrate was maintained at about 250 °C.

As the first precursor (Dy precursor), Dy(iPrCp)₂(iPr-N-amd) was used. The first precursor was stored in a stainless-steel canister, and a delivery line for the first precursor was heated to 150 °C to prevent condensation of the first precursor. The first precursor was vaporized at 140 °C, and argon (Ar) as a carrier gas was supplied at a flow rate of 90 sccm (with a vapor pressure of 30 mTorr or less).

By a plasma-enhanced ALD deposition process, the vaporized first precursor was supplied into the reaction chamber through the carrier gas and deposited on the target substrate, thereby forming a first deposition layer. At this time, a plasma frequency was set to 13.56 MHz and a plasma power was set to 300 W, and ALD deposition was performed with an exposure time set to 1 second, 2 seconds, 3 seconds, or 4 seconds, respectively. A reaction temperature was maintained at about 250 °C.

Next, argon (Ar) gas was introduced into the chamber at a flow rate of 600 sccm, and purging was performed for 60 seconds.

Next, as the second precursor (Hf precursor), tetrakis(ethylmethylamido) hafnium (IV) was used. The second precursor was stored in a stainless-steel canister, and a delivery line for the second precursor was heated to 70 °C to prevent condensation of the second precursor. The second precursor was vaporized at 50 °C, and argon (Ar) as a carrier gas was supplied at a flow rate of 20 sccm (with a vapor pressure of 30 mTorr or less).

By a plasma-enhanced ALD deposition process, the vaporized second precursor was supplied into the reaction chamber through the carrier gas and deposited on the first deposition layer on the target substrate, thereby forming a second deposition layer. At this time, a plasma frequency was set to 13.56 MHz and a plasma power was set to 300 W, and ALD deposition was performed with an exposure time of 3 seconds. A reaction temperature was maintained at about 250 °C.

Next, argon (Ar) gas was introduced into the chamber at a flow rate of 600 sccm, and purging was performed for 60 seconds.

Next, a mixed gas of O₂ as a reactant and He was supplied at a flow rate of 100 sccm and subjected to plasma-enhanced ALD deposition on the target substrate on which the first and second precursors had been deposited. At this time, a plasma frequency was set to 13.56 MHz and a plasma power was set to 300 W, and deposition was performed for 5 seconds. A reaction temperature was maintained at about 250 °C, thereby preparing an ultrathin film having a thickness of 5 nm and comprising a compound represented by Chemical Formula 1. The molar ratios a, b, and c of Chemical Formula 1 are shown in Table 1 below.

(Dy)ₐHf_{b}O_{c} [Chemical Formula 1]

In Chemical Formula 1, a, b, and c represent molar ratios, and a+b+c=1.

### Example 2: Preparation of Ultrathin Film by Horizontally Doped ALD (First Precursor=Hf Precursor)

An ultrathin film having a thickness of 5 nm and comprising a compound represented by Chemical Formula 1 was prepared under the same conditions as in Example 1, except that, during formation of the first deposition layer, tetrakis(ethylmethylamido) hafnium (IV) as an Hf precursor was used as the first precursor instead of the Dy precursor. In this case, ALD deposition was performed with an exposure time set to 1 second, 2 seconds, 3 seconds, or 4 seconds, respectively. In addition, Dy(iPrCp)₂(iPr-N-amd) as a Dy precursor was used as the second precursor instead of the Hf precursor. In addition, the molar ratios a, b, and c of Chemical Formula 1 are shown in Table 1 below.

### Comparative Example 1: Preparation of Single HfO₂ Thin Film

As a precursor (Hf precursor), tetrakis(ethylmethylamido) hafnium (IV) was used. The precursor was stored in a stainless-steel canister, and a delivery line for the precursor was heated to 70 °C to prevent condensation of the precursor. The precursor was vaporized at 50 °C, and argon (Ar) as a carrier gas was supplied at a flow rate of 50 sccm to perform ALD deposition, thereby preparing a single thin film having a thickness of 5 nm and comprising HfO₂.

### Comparative Example 2: Preparation of Single Dy₂O₃ Thin Film

As a precursor (Dy precursor), Dy(iPrCp)₂(iPr-N-amd) was used. The precursor was stored in a stainless-steel canister, and a delivery line for the precursor was heated to 150 °C to prevent condensation of the precursor. The precursor was vaporized at 140 °C, and argon (Ar) as a carrier gas was supplied at a flow rate of 90 sccm to perform ALD deposition, thereby preparing a single thin film having a thickness of 5 nm and comprising Dy₂O₃.

### Experimental Example 1: Chemical Composition Analysis of Ultrathin Films

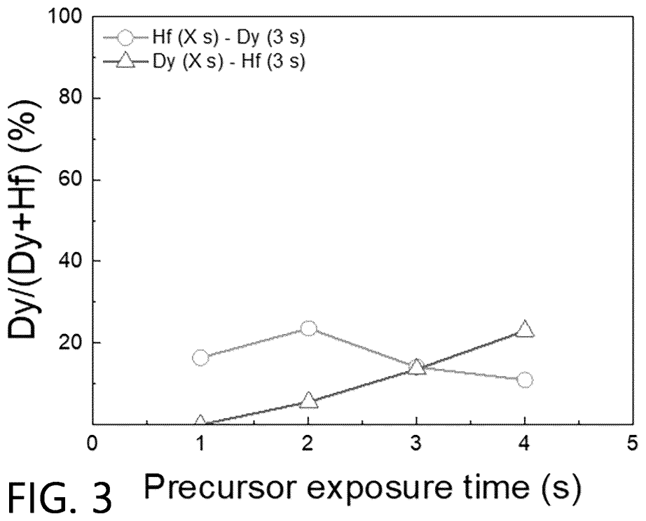

For the ultrathin films prepared in Example 1 and Example 2, which were manufactured by varying the exposure time of the first precursor during formation of the first deposition layer, atomic concentrations of the ultrathin films and molar ratios a, b, and c of the compounds represented by Chemical Formula 1 are shown in Table 1 below. In addition, Dy concentration measurements according to the order and exposure time of the first precursor in Examples 1 and 2 are shown in FIG. 3.

TABLE 1

| | | Atomic Concentration | | | | | Dy/ | |
|---|---|---|---|---|---|---|---|---|
| | Exposure | (atom %) | | | | | (Dy + | |
| Process | Time (s) | Dy | Hf | O | C | N | Hf) | DyₐHf_{b}O_{c} |
| Example 1 | 1 | <1 | 32.0 | 68.0 | <1 | <1 | <1 | a = 0.001, |
| (Dy 1^{st}) | | | | | | | | b = 0.320, |
| | | | | | | | | c = 0.679 |
| | 2 | 1.9 | 31.5 | 66.6 | <1 | <1 | 5.6 | a = 0.019, |
| | | | | | | | | b = 0.315, |
| | | | | | | | | c = 0.666 |
| | 3 | 4.6 | 29.4 | 65.9 | <1 | <1 | 13.5 | a = 0.046, |
| | | | | | | | | b = 0.294, |
| | | | | | | | | c = 0.659 |
| | 4 | 8.1 | 27.2 | 64.6 | <1 | <1 | 23.0 | a = 0.081, |
| | | | | | | | | b = 0.272, |
| | | | | | | | | c = 0.646 |
| Example 2 | 1 | 7.9 | 25.7 | 66.3 | <1 | <1 | 16.4 | a = 0.079, |
| (Hf 1^{st}) | | | | | | | | b = 0.257, |
| | | | | | | | | c = 0.663 |
| | 2 | 8.4 | 27.3 | 64.3 | <1 | <1 | 23.5 | a = 0.084, |
| | | | | | | | | b = 0.273, |
| | | | | | | | | c = 0.643 |
| | 3 | 4.7 | 28.9 | 66.4 | <1 | <1 | 14.0 | a = 0.047, |
| | | | | | | | | b = 0.289, |
| | | | | | | | | c = 0.662 |
| | 4 | 3.6 | 29.3 | 67.0 | <1 | <1 | 11.0 | a = 0.036, |
| | | | | | | | | b = 0.293, |
| | | | | | | | | c = 0.670 |

From Table 1, it can be confirmed that a composition ratio of Dy in the ultrathin film can be varied by adjusting an exposure time of the first precursor.

### Experimental Example 2: Measurement of ALD Growth Curves

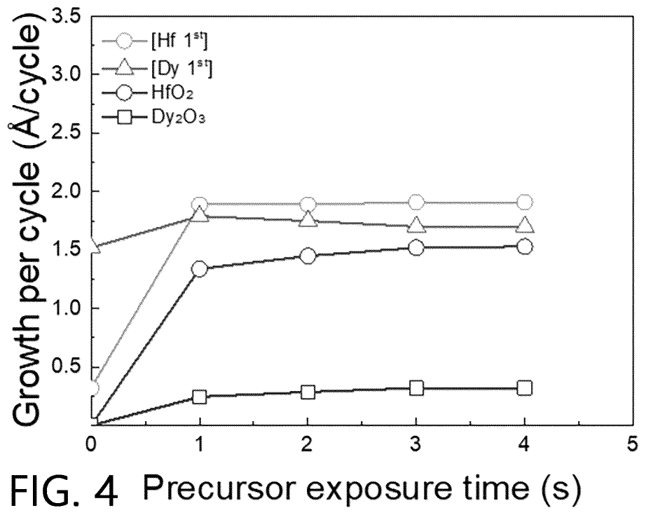

ALD growth per cycle (GPC) curves for the ultrathin films of Examples 1 and 2 and Comparative Examples 1 and 2, which were prepared by varying the exposure time of the first precursor, are shown in FIG. 4.

In FIG. 4, a red line represents the growth characteristics of Comparative Example 1 (HfO₂), and a blue line represents the growth characteristics of Comparative Example 2 (Dy₂O₃). In the case of Comparative Example 1 (HfO₂), a GPC of 1.5 Å/cycle at an exposure time of 3 seconds was observed, and in the case of Comparative Example 2(Dy₂O₃), a GPC of 0.3 Å/cycle at an exposure time of 3 seconds was observed.

In the case of Example 1 (Dy^{1st}), a GPC of 1.7 Å/cycle was obtained, and in the case of Example 2 (Hf^{1st}), a GPC of 1.9 Å/cycle was obtained.

### Experimental Example 3: Crystallinity Analysis of Annealed Ultrathin Films

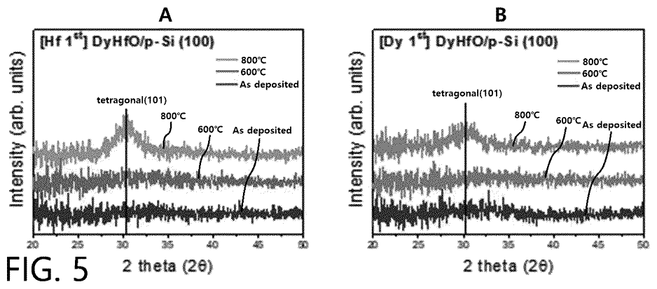

X-ray diffraction (XRD) analysis was performed on an ultrathin film (Dy^{1st}) prepared in Example 1 by exposing a Dy precursor as the first precursor for an exposure time of 3 seconds, and on an ultrathin film (Hf^{1st}) prepared in Example 2 by exposing an Hf precursor as the first precursor for an exposure time of 3 seconds, and the results thereof are shown in FIGS. 5A and 5B.

In addition, each of the ultrathin films was subjected to annealing at 600 °C or 800 °C for 10 minutes under a nitrogen exposure condition of 200 sccm, and X-ray diffraction analysis results of the annealed ultrathin films are also shown in FIGS. 5A and 5B.

As shown in FIG. 5, no crystallinity was observed in either the as-deposited ultrathin films or the ultrathin films annealed at 600 °C.

However, for both the ultrathin film of Example 1 and the ultrathin film of Example 2 that were annealed at 800 °C, diffraction peaks were observed in a range of 30° to 32°, indicating that both ultrathin films exhibit a tetragonal crystal structure.

### Experimental Example 4: Evaluation of Leakage Current Characteristics

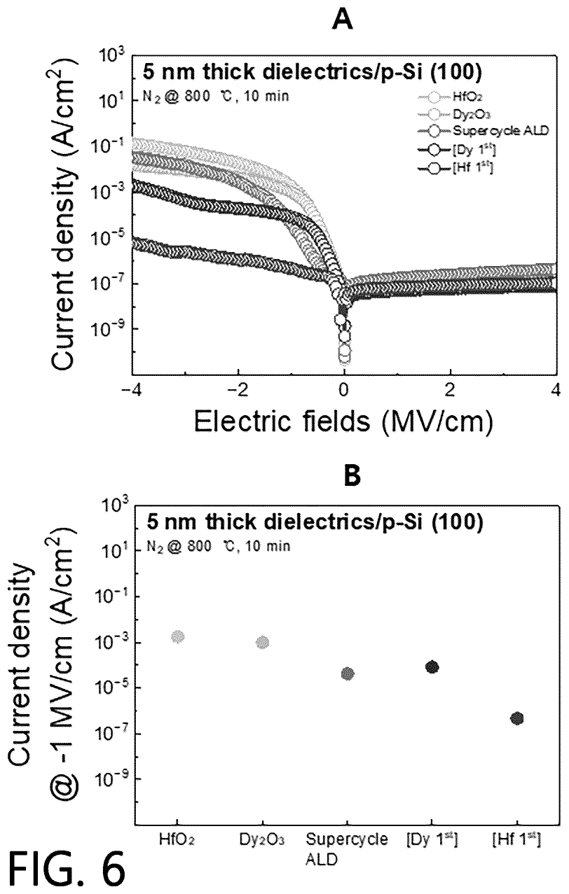

Leakage current characteristics of the ultrathin films of Example 1 (Dy^{1st}) and Example 2(Hf^{1st}), which were annealed at 800 °C in Experimental Example 3, were evaluated by the following method, and the results are shown in FIGS. 6A and 6B.

In addition, the ultrathin films prepared in Comparative Example 1 (HfO₂) and Comparative Example 2(Dy₂O₃) were also annealed at 800 °C using the same method as in Experimental Example 3, and measurement results of leakage current characteristics thereof are additionally shown together in FIG. 6A.

The leakage current characteristics were evaluated by fabricating a device having a MOSFET-type stacked structure including an aluminum (Al) electrode/ultrathin film/silicon/silver paste, and performing measurements using a manual probe-based current-voltage (I-V) measurement method.

As shown in FIG. 6A, in the case of the 5 nm-thick single films of Comparative Example 1 (HfO₂) and Comparative Example 2(Dy₂O₃), leakage current densities of 1.78×10⁻³ A/cm² and 9.94×10⁻⁴ A/cm², respectively, were observed at an electric field of −1 MV/cm.

In contrast, in the case of Example 1 (Dylst), a leakage current density of 8.21×10⁻⁵ A/cm² was observed at −1 MV/cm, and in the case of Example 2(Hf^{1st}), a leakage current density of 8.21×10⁻⁷ A/cm² was observed at −1 MV/cm.

From these results, it was confirmed that, at the same thickness, a lower leakage current can be achieved by an ALD process producing a horizontally doped ultrathin film, as compared with a conventional vertically doped single-film ALD process.

Based on the above Examples and Experimental Examples, it was further confirmed that, in forming an ultrathin film using atomic layer deposition (ALD), an ultrathin film can be formed as a horizontally doped ultrathin film rather than a vertically doped ultrathin film, thereby providing an ultrathin film and a method for manufacturing the same that overcome the material property limitations of ultrathin films manufactured by conventional vertically doped ALD methods.

What is claimed is:

1. A method for manufacturing a dysprosium (Dy)-doped hafnium oxide ultrathin film by an atomic layer deposition (ALD) process, the method comprising performing the ALD process using one super cycle including a first step to a sixth step,
wherein the one super cycle comprises:
a first step of supplying a vaporized first precursor into a reaction chamber through a carrier gas to form a first deposition layer on a target substrate;
a second step of purging an interior of the reaction chamber with a purge gas;
a third step of supplying a vaporized second precursor into the reaction chamber to form a second deposition layer on the first deposition layer;
a fourth step of purging the interior of the reaction chamber after performing the third step with the purge gas;
a fifth step of introducing and reacting an O₂-containing gas into the reaction chamber after performing the fourth step; and
a sixth step of purging the interior of the reaction chamber after performing the fifth step with the purge gas,
wherein the first precursor and the second precursor each comprise a hafnium (Hf) precursor or a dysprosium (Dy) precursor, and
wherein the first precursor and the second precursor are different from each other.

2. The method of claim 1, wherein the one super cycle is repeatedly performed multiple times.

3. The method of claim 1, wherein the ALD process is performed by a plasma-enhanced atomic layer deposition (PE-ALD) process.

4. The method of claim 1,
wherein a temperature of the target substrate in the first step is 200 °C to 275 °C, and
each of the first step, the third step, and the fifth step is performed at a process temperature of 200 °C to 275 °C.

5. The method of claim 1, further comprising performing an annealing process after completion of the ALD process.

6. The method of claim 1, wherein an ultrathin film represented by Chemical Formula 1, which is formed by performing the sixth step, is annealed at a temperature of 500 °C to 900 °C under a vacuum atmosphere or an inert gas atmosphere:
(Dy)ₐHf_{b}O_{c} [Chemical Formula 1]
wherein, in Chemical Formula 1, a, b, and c represent molar ratios, and when a +b+c=1, a satisfies 0.001≤a≤0.010 and b satisfies 0.250≤b≤0.350.

7. The method of claim 6, wherein, when the annealing temperature is lower than 700 °C, the annealed ultrathin film has an amorphous structure.

8. The method of claim 6, wherein, when the annealing temperature exceeds 700 °C, the annealed ultrathin film has a tetragonal crystal structure.

9. The method of claim 1,
wherein the hafnium (Hf) precursor comprises at least one selected from the group consisting of HfCl₄, tetrakis(ethylmethylamido) hafnium (IV), tetrakis(dimethylamido) hafnium (IV), and Cp-Hf, and
wherein the dysprosium (Dy) precursor comprises at least one selected from the group consisting of Dy(iPrCp)₂(iPr-N-amd), DyCl₃, and tris(2,2,6,6-tetramethyl-3,5-heptanedionato) dysprosium (III).

10. The method of claim 1, wherein, after completion of the ALD process, an oxidation barrier layer is further formed on an exposed outer surface of the ALD-deposited layer, and an annealing process is then performed.

11. The method of claim 10, wherein the oxidation barrier layer is a silicon nitride (SiNₓ) ALD-deposited layer having a thickness of 1 to 10 nm.

12. An horizontally doped atomic layer deposition (ALD) ultrathin film manufactured by the method of any one of claim 1, the ultrathin film comprising a compound represented by Chemical Formula 1 and having a thickness of 10 nm or less:
(Dy)ₐHf_{b}O_{c} [Chemical Formula 1]
wherein, in Chemical Formula 1, a, b, and c represent molar ratios, and when a +b+c=1, a satisfies 0.001≤a≤0.010 and b satisfies 0.250≤b≤0.350.

13. An horizontally doped atomic layer deposition (ALD) ultrathin film, the ultrathin film comprising a compound represented by Chemical Formula 1 and having a thickness of 10 nm or less:
(Dy)ₐHf_{b}O_{c} [Chemical Formula 1]
wherein, in Chemical Formula 1, a, b, and c represent molar ratios, and when a +b+c=1, a satisfies 0.001≤a≤0.010 and b satisfies 0.250≤b≤0.350.

14. The horizontally doped ALD ultrathin film of claim 13,
wherein, when the ultrathin film is a single thin film having a thickness of 4.5 nm to 5.5 nm,
the ultrathin film has a current density of 1.0×10⁻⁷ A/cm² to 9.0×10⁻⁵ A/cm² at an electric field of −1 MV/cm, as measured by a manual probe contact-type current-voltage measurement method.

15. A semiconductor comprising the ultrathin film of claim 13.
